(19) United States
(12) Patent Application Publication
(10) Pub. No.: US 2019/0087125 A1
(43) Pub. Date: Mar. 21, 2019

(54) MEMORY SYSTEM AND CONTROL METHOD OF MEMORY SYSTEM

(71) Applicant: TOSHIBA MEMORY CORPORATION, Tokyo (JP)

(72) Inventors: Mariko MATSUMOTO, Kawasaki Kanagawa (JP); Masaaki TAMURA, Chigasaki Kanagawa (JP); Takamasa HIRATA, Kodaira Tokyo (JP)

(21) Appl. No.: 15/908,832

(22) Filed: Mar. 1, 2018

(30) Foreign Application Priority Data
Sep. 19, 2017 (JP) 2017-179505

(51) Int. Cl. G06F 3/06; G11C 16/34; G06F 12/0868

(52) U.S. Cl. CPC G06F 3/0659; G11C 16/3431; G06F 3/0619; G11C 16/0483; G06F 3/0679; G06F 12/0868; G06F 3/0653

(57) ABSTRACT

A memory system includes a non-volatile memory device and a memory controller. The memory controller includes a first counting circuit configured to count a number of times reading is performed on a first unit of data, a second counting circuit configured to count a number of times reading is performed on a second unit of data, which has a size smaller than that of the first unit of data and is a part of the first unit of data, when the number of times reading has been performed on the first unit of data exceeds a first threshold value, and a cache control circuit configured to cache the second unit of data in response to a read request for the second unit of data, when the number of times reading has been performed on the second unit of data exceeds a second threshold value.

### CROSS-REFERENCE TO RELATED APPLICATION

This application is based upon and claims the benefit of priority from Japanese Patent Application No. 2017-179505, filed Sep. 19, 2017, the entire contents of which are incorporated herein by reference.

### FIELD

Embodiments described herein relate generally to a memory system and a control method of the memory system.

### BACKGROUND

A memory system such as a solid state drive (SSD) employing a NAND-type flash memory chip as a storage medium has been known. In general, the deterioration of the NAND-type flash memory chip from wear worsens as the number of times of access increases. Therefore, in the related art, for example, data read by a host a large number of times is stored in a cache area such as a RAM so as to reduce the number of times access is made to the NAND-type flash memory chip.

However, a cache area occupied by the memory system is limited. Therefore, in order to further reduce the number of times access is made to the NAND-type flash memory chip, the limited cache area needs to be utilized more effectively.

### DESCRIPTION OF THE DRAWINGS

FIG. 1 is a schematic view of a memory system according to a first embodiment.

FIG. 2 is a schematic view of a management unit of data in the memory system according to the first embodiment.

FIG. 3 is a schematic view of functions of a memory controller of the first embodiment.

FIG. 4 is a graph illustrating an example of a statistical start threshold value and a refresh threshold value used in the first embodiment.

FIG. 5 is a graph illustrating an example of a count result of the number of times of each group of a logical block has been read, used in the first embodiment.

FIG. 6 is a flow chart illustrating an example of a procedure of a first count processing according to the first embodiment.

FIG. 7 is a flow chart illustrating an example of a procedure of a second count processing according to the first embodiment.

FIG. 8 is a schematic view of a memory system according to a second embodiment.

FIG. 9 is a schematic view of functions of a memory controller of the second embodiment.

FIG. 10 is a flow chart illustrating an example of a procedure of a first count processing according to the second embodiment.

FIG. 11 is a flow chart illustrating an example of a procedure of a second count processing according to the second embodiment.

### DETAILED DESCRIPTION

Embodiments provide a memory system and a control method of the memory system, in which an amount of data to be cached is controlled so that wear on a NAND-type flash memory chip can be delayed.

In general, according to one embodiment, a memory system includes a non-volatile memory device and a memory controller that controls the memory device. The memory controller includes a first counting circuit configured to count a number of times reading is performed on a first unit of data, wherein the memory controller is configured to erase data of the first unit of data collectively, a second counting circuit configured to count a number of times reading is performed on a second unit of data, which has a size smaller than that of the first unit of data and is a part of the first unit of data, when the number of times reading has been performed on the first unit of data exceeds a first threshold value, and a cache control circuit configured to cache the second unit of data in response to a read request for the second unit of data, when the number of times reading has been performed on the second unit of data exceeds a second threshold value.

Hereinafter, a memory system and a control method of the memory system according to embodiments will be described in detail with reference to the accompanying drawings. Meanwhile, the present disclosure is not limited by the embodiments.

### First Embodiment

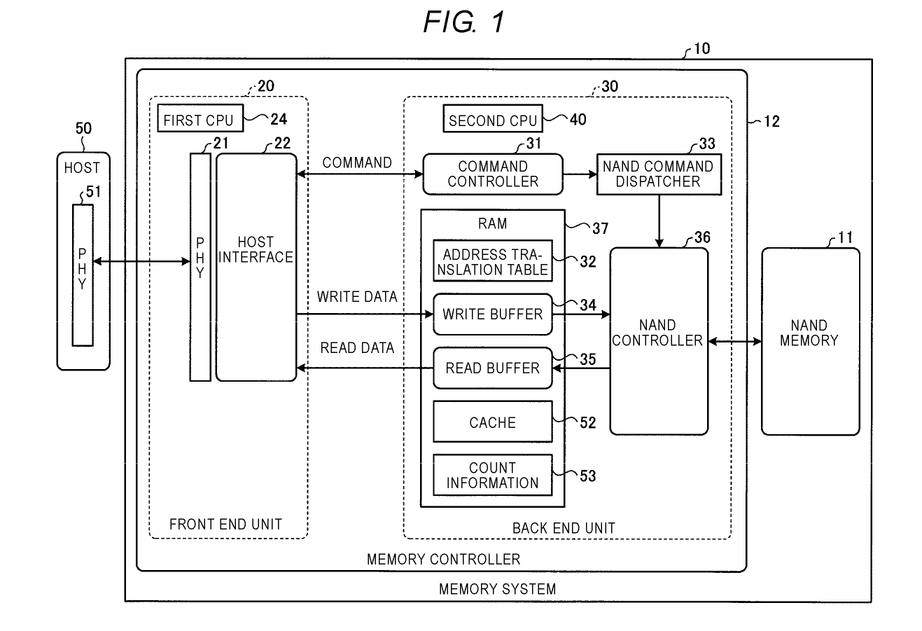

FIG. 1 is a view schematically illustrating an example of an entire configuration of a memory system 10 according to the present embodiment. As illustrated in FIG. 1, the memory system 10 includes a NAND-type flash memory (hereinafter, referred to as a NAND memory) 11, and a memory controller 12. An example of the memory system 10 is a solid state drive (SSD) using the NAND memory 11 as a storage medium.

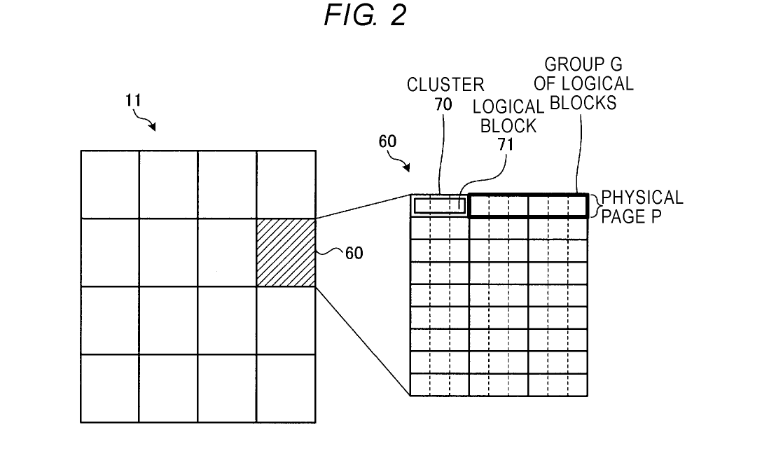

The NAND memory 11 is a storage medium capable of storing information in a non-volatile manner. The NAND memory 11 stores, for example, user data transmitted from a host 50, management information of the memory system 10, system data and others. The NAND memory 11 is configured with, for example, a plurality of memory chips, and each memory chip includes a plurality of physical blocks. Details of the NAND memory 11 will be described later in FIG. 2. The NAND memory 11 is an example of a memory unit in the present embodiment.

The memory controller 12 writes data into the NAND memory 11 or reads data from the NAND memory 11, according to a command from the host 50. The memory controller 12 includes a front end unit 20 and a back end unit 30.

The front end unit 20 has a function of passing a command received from the host 50 to the backend unit 30, and returning a response to the command from the back end unit 30, to the host 50. The front end unit 20 is an example of a first circuit unit in the present embodiment.

The front end unit 20 includes a physical layer chip (PHY) 21, a host interface 22, and a first CPU 24.

The first CPU 24 controls the front end unit 20 based on firmware. The first CPU 24 can perform various controls by executing a program read from a memory device such as a ROM (not illustrated).

The PHY 21 corresponds to an input/output unit for the memory controller 12, and exchanges electrical signals with a PHY 51 corresponding to an input/output unit of the host 50.

The host interface 22 performs a protocol conversion between the back end unit 30 and the host 50, and controls transfer (transmission/reception) of data, commands, and addresses.

The back end unit 30 has a function of writing and reading data in/from the NAND memory 11, based on a command from the front end unit 20. The back end unit 30 is an example of a second circuit unit in the present embodiment.

The back end unit 30 includes a command controller 31, a NAND command dispatcher 33 (hereinafter, referred to as a dispatcher 33), a NAND controller 36, a RAM 37, and a second CPU 40.

The RAM 37 stores an address translation table 32, a write buffer 34, a read buffer 35, a cache 52, and a count information 53. The RAM 37 is, for example, a static random access memory (SRAM), a dynamic random access memory (DRAM), a synchronous dynamic random access memory (SDRAM) or the like.

The address translation table 32 is information indicating a correspondence relationship between a logical address specified by a command, and a physical address of the NAND memory 11. More specifically, the address translation table 32 is information storing a mapping between information on a certain physical location within a physical block that is an erasable unit of data stored in the NAND memory 11, and a management unit of data (such as a physical page P, a cluster 70, a logical block 71, and a group G) which indicates a data size smaller than that of the physical block. The management unit of data will be described later in FIG. 2.

The address translation table 32 is read from the NAND memory 11 and stored in the RAM 37 when the memory system 10 is activated. The address translation table 32 is updated as the correspondence relationship between the logical address and the physical address changes. The address translation table 32 is stored in the NAND memory 11 at a predetermined timing (e.g., at the time of power shutoff, at every predetermined time, or the like).

The write buffer 34 temporarily stores data to be written in the NAND memory 11. As a write command is passed from the front end unit 20 to the back end unit 30, data is transferred to the write buffer 34. The data is transferred via the host interface 22.

The read buffer 35 temporarily stores data read from the NAND memory 11. The data is written in the read buffer 35 via the NAND controller 36.

The cache 52 is a data area in which a part of data stored in the NAND memory 11 is cached. The cache 52 is a read cache. When data as a target to be read by the host 50 is stored in the cache 52, the target data is read from the cache 52, rather than from the NAND memory 11. The cache 52 may be provided in a DRAM or the like outside the memory controller 12.

The count information 53 is a count result of the number of times data stored in the NAND memory 11 is read. More specifically, for each management unit of data to be described later in FIG. 2, the counted number of times of reading is stored in the RAM 37.

The second CPU 40 controls the back end unit 30 based on firmware. The second CPU 40 can perform various controls by executing a program read from a memory device such as a ROM (not illustrated).

When receiving a command from the front end unit 20, the command controller 31 identifies (determines) the type of the command (e.g., a write request command, a read request command, or the like), and passes the command to the dispatcher 33.

The dispatcher 33 converts the command from the front end unit 20 into a command to be passed to the NAND controller 36, and sends the command to the NAND controller 36.

The NAND controller 36 controls reading or writing of data from/in the NAND memory 11, based on an address. For example, when receiving a write command from the dispatcher 33, the NAND controller 36 acquires write data from the write buffer 34 based on the write command, and writes the write data in the NAND memory 11. When receiving a read command from the dispatcher 33, the NAND controller 36 reads read data from the NAND memory 11 based on the read command, and stores the read data in the read buffer 35.

FIG. 2 is a view schematically illustrating an example of a management unit of data in the memory system 10 according to the present embodiment. As illustrated in FIG. 2, the NAND memory 11 includes a plurality of physical blocks 60.

Each physical block 60 is a unit by which data is erasable collectively in the NAND memory 11. A physical page P is a unit by which data is writable and readable in/from the NAND memory 11. One physical block 60 includes a plurality of physical pages P. The reading and writing of data from/in the NAND memory 11 are collectively referred to as an access to the NAND memory 11.

The logical block 71 is a minimum unit of an access from the host 50. As indicated by the broken line in FIG. 2, a plurality of logical blocks 71 are included in one physical block 60. The logical block 71 is specified by, for example, a logical block addressing (LBA). The logical block 71 is also called a sector.

A plurality of physical pages P are included in one physical block 60, and each physical page P includes a plurality of clusters. The physical page P is a unit by which data is writable and readable in/from the NAND memory 11.

The cluster 70 is a unit smaller than the physical page P and indicating a data size larger than that of the logical block 71. More specifically, the cluster 70 is a unit obtained by dividing the physical page P by a predetermined data size and includes a plurality of logical blocks 71.

As indicated by the double line in FIG. 2, one cluster 70 includes three logical blocks 71. One physical page P includes three clusters 70. The number of the logical blocks 71 included in the cluster 70 and the number of the clusters 70 included in the physical page P in FIG. 2 are only given as examples, and the present disclosure is not limited thereto.

As illustrated in FIG. 2, according to data associated with the logical blocks 71, a group G of logical blocks (hereinafter, referred to as a group G) which includes the plurality of logical blocks 71 is generated. When data is written in the physical block 60, the plurality of logical blocks 71 associated with a data area in which the data is written are generated as one group G. The group G is also a unit by which a read request is made from the host 50. The range of the data area indicated by the group G (that is, the logical blocks 71 included in the group G) is determined when data is written in the NAND memory 11. For example, the group G illustrated in FIG. 2 includes six logical blocks 71. The number of the logical blocks 71 included in the group G in FIG. 2 is only given as example, and the present disclosure is not limited thereto. The number of the logical blocks 71 included in the group G may vary depending on groups G.

In general, the group G of the logical blocks 71 is a unit larger than the cluster 70. In FIG. 2, as indicated by the range surrounded by the thick line, the range of the group G includes, for example, two clusters 70. Otherwise, the group G of the logical blocks 71 may have the same size as the cluster 70.

The correspondence (mapping) between respective units (the physical block 60, the physical page P, the cluster 70, the logical block 71, and the group G) in the access or management of data is stored in the address translation table 32. The size of each management unit of data illustrated in FIG. 2 is only given as an example, and the present disclosure is not limited thereto.

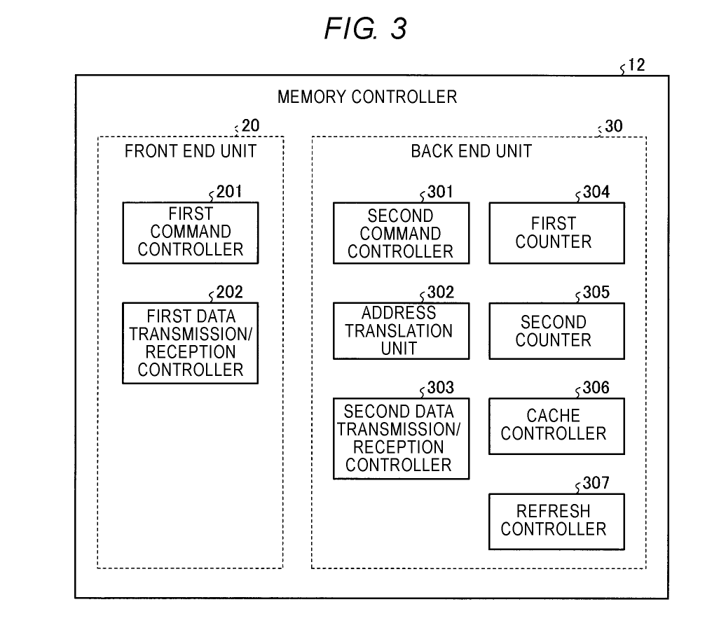

FIG. 3 is a view schematically illustrating an example of a function of the memory controller 12 according to the present embodiment. As illustrated in FIG. 3, the front end unit 20 of the memory controller 12 includes a first command controller 201 and a first data transmission/reception controller 202.

The first command controller 201 controls transmission/reception of a command. More specifically, the first command controller 201 controls the host interface 22 such that a command received by the PHY 21 from the host 50 is passed to the back end unit 30.

The first data transmission/reception controller 202 controls transmission/reception of data. More specifically, the first data transmission/reception controller 202 controls the host interface 22 and the PHY 21 such that data transmitted from the back end unit 30 is transmitted to the host 50, according to a command of a read request from the host 50.

Each functional unit of the front end unit 20 (e.g., the first command controller 201 and the first data transmission/reception controller 202) is implemented by a hardware circuit. Alternatively, each functional unit of the front end unit 20 may be implemented when the first CPU 24 executes a program from a memory device.

The backend unit 30 of the memory controller 12 includes a second command controller 301, an address translation unit 302, a second data transmission/reception controller 303, a first counter 304, a second counter 305, a cache controller 306, and a refresh controller 307.

The second command controller 301 controls the command controller 31, the dispatcher 33, and the NAND controller 36 so as to control the delivery of a command transmitted from the front end unit 20 within the back end unit 30. More specifically, the second command controller 301 controls the delivery of a command received by the command controller 31 from the front end unit 20 to the dispatcher 33. The second command controller 301 controls the delivery of a command from the dispatcher 33 to the NAND controller 36.

The address translation unit 302 translates a logical address specified by a command transmitted from the front end unit 20 into a physical address of the NAND memory 11 using the address translation table 32, and passes the physical address to the dispatcher 33. Alternatively, the translation from the logical address into the physical address may be performed by the dispatcher 33.

The second data transmission/reception controller 303 controls the command controller 31 and the NAND controller 36 so as to control transmission/reception of data between the front end unit 20 and the NAND memory 11.

The first counter 304 counts the number of times of reading by the host 50 from the NAND memory 11, for each physical block 60. More specifically, the first counter 304 acquires a physical address obtained through translation by the address translation unit 302 based on a received command, specifies the physical block 60 to be read according to the command, and updates the number of times of reading of the physical block 60, which is stored in the count information 53. The physical block 60 is an example of a first count unit in the present embodiment. A count processing performed by the first counter 304 is referred to as a first count processing.

The first counter 304 counts the number of times of reading from the NAND memory 11. Thus, when data as a reading target is stored in the cache 52, the number of times of reading is not counted.

When the number of times of reading of a certain physical block 60 exceeds a predetermined statistical start threshold value, the first counter 304 specifies a group G included in (associated with) the physical block 60 using the address translation table 32. The first counter 304 notifies the second counter 305 of the specified group G. Otherwise, the first counter 304 may notify the second counter 305 of the physical block 60 for which the number of times of reading exceeds a statistical start threshold value, and then, the second counter 305 may specify a group G.

The statistical start threshold value is a threshold value serving as a reference used for discerning whether the group G included in the physical block 60 is a target for which the number of times of reading is to be counted. The statistical start threshold value is determined in advance as a value smaller than a refresh threshold value serving as a reference used for refreshing the physical block 60. The statistical start threshold value is an example of a first threshold value in the present embodiment. The refresh threshold value is an example of a third threshold value in the present embodiment.

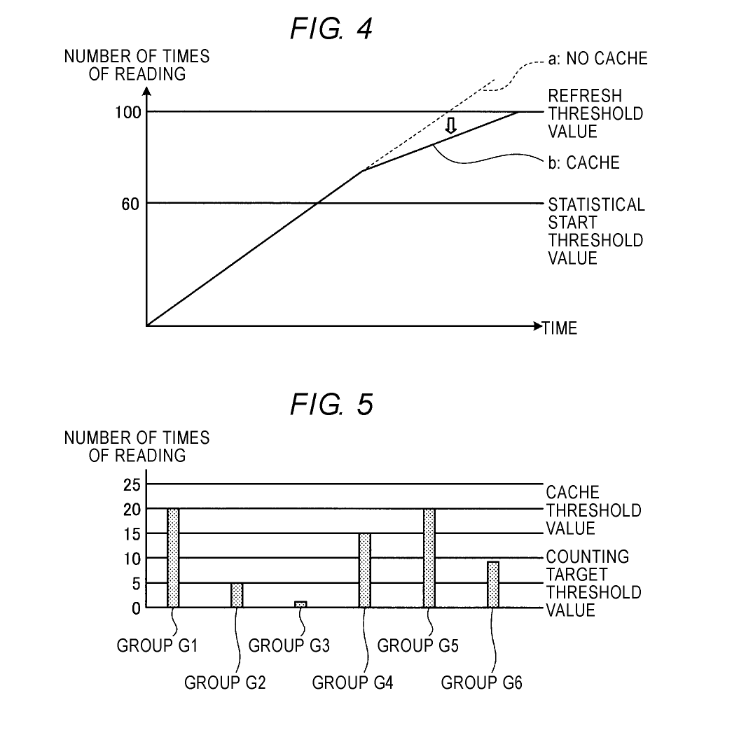

FIG. 4 is a graph illustrating an example of a statistical start threshold value and a refresh threshold value according to the present embodiment. In the graph of FIG. 4, the vertical axis indicates the number of times of reading of a certain physical block 60, and the horizontal axis indicates a time. For example, it is assumed that when the number of times of reading of the physical block 60 exceeds “100” as an example of the refresh threshold value, the physical block 60 is refreshed by the refresh controller 307 to be described later. The statistical start threshold value is a value smaller than the refresh threshold value, and may be, for example, “60.” The refresh threshold value and the statistical start threshold value illustrated in FIG. 4 are given as examples only, and the present disclosure is not limited thereto.

When the physical block 60 is refreshed by the refresh controller 307 to be described later, the first counter 304 returns the number of times of reading of the physical block 60, which is stored in the count information 53, to “0.”

Referring back to FIG. 3, the second counter 305 counts the number of times of reading for each group G included in the physical block 60 for which the number of times of reading exceeds the statistical start threshold value. More specifically, the second counter 305 specifies the group G including the logical blocks 71 specified by a command transmitted from the front end unit 20, and updates the number of times of reading of the group G, which is stored in the count information 53, when the group G is a counting target. The group G is an example of a second count unit in the present embodiment. The count processing performed by the second counter 305 is referred to as a second count processing.

The second counter 305 counts the number of times of reading from the NAND memory 11. Thus, when data as a reading target is cached in the cache 52, the number of times of reading is not counted.

FIG. 5 is a graph illustrating an example of a count result of the number of times of reading for each group G according to the present embodiment. For example, it is assumed that one physical block 60 is associated with six groups G1 to G6. As illustrated in FIG. 5, the second counter 305 counts the number of times of reading by the host 50, for each of the groups G1 to G6.

The second counter 305 may exclude the group G for which the number of times of reading does not exceed a counting target threshold value even after counting for a predetermined period of time, from a counting target. For example, as illustrated in FIG. 5, in the case where the counting target threshold value is set as “5,” when the number of times of reading of the group G3 does not exceed “5” even after counting for a predetermined period of time, the second counter 305 may exclude the group G3 from the counting target. The counting target threshold value illustrated in FIG. 5 is given as an example only, and the present disclosure is not limited thereto.

When the number of times of reading of a certain group G exceeds a predetermined cache threshold value (e.g., “20”), the second counter 305 notifies the cache controller 306 of the group G. The cache threshold value is set as a value smaller than the statistical start threshold value. The cache threshold value illustrated in FIG. 5 is given as an example only, and the present disclosure is not limited thereto. The cache threshold value is an example of a second threshold value in the present embodiment.

When the physical block 60 is refreshed by the refresh controller 307 to be described later, the second counter 305 returns the number of times of reading of the group G associated with the physical block 60, which is stored in the count information 53, to “0.” When data is written in the logical blocks 71 according to a write request from the host 50, the second counter 305 returns the number of times of reading of the group G including the logical blocks 71, which is stored in the count information 53, to “0.”

Referring back to FIG. 3, the cache controller 306 caches data stored in a data area indicated by the group G for which the number of times of reading exceeds the cache threshold value, in the cache 52. The cache controller 306 of the present embodiment sets data indicated by the group G included in the physical block 60, as a cache target. Thus, an increase of an amount of data to be cached can be prevented, as compared to the case where caching is performed per unit of the physical block 60.

When a write request is made for the logical blocks 71, the cache controller 306 invalidates data associated with the logical blocks 71 among cache data stored in the cache 52. When there is cache data that is associated with an already refreshed physical block 60, among cache data stored in the cache 52, the cache controller 306 may newly overwrite the data with data associated with the group G for which the number of times of reading exceeds the cache threshold value.

The refresh controller 307 refreshes the physical block 60 for which the number of times of reading exceeds the refresh threshold value. The refresh controller 307 notifies the first counter 304, the second counter 305, and the cache controller 306 of the refreshed physical block 60.

Referring back to FIG. 4, the broken line “a” indicates an assumed value of the number of times of reading when caching of data is not performed. The solid line “b” indicates a value of the number of times of reading when data having a large number of times of reading is cached by the cache controller 306. When the cache controller 306 caches data having a large number of times of reading, the number of times of reading from the NAND memory 11 is reduced. Therefore, it is possible to delay the number of times of reading for each physical block 60 from exceeding the refresh threshold value, and to reduce the number of times of refreshing.

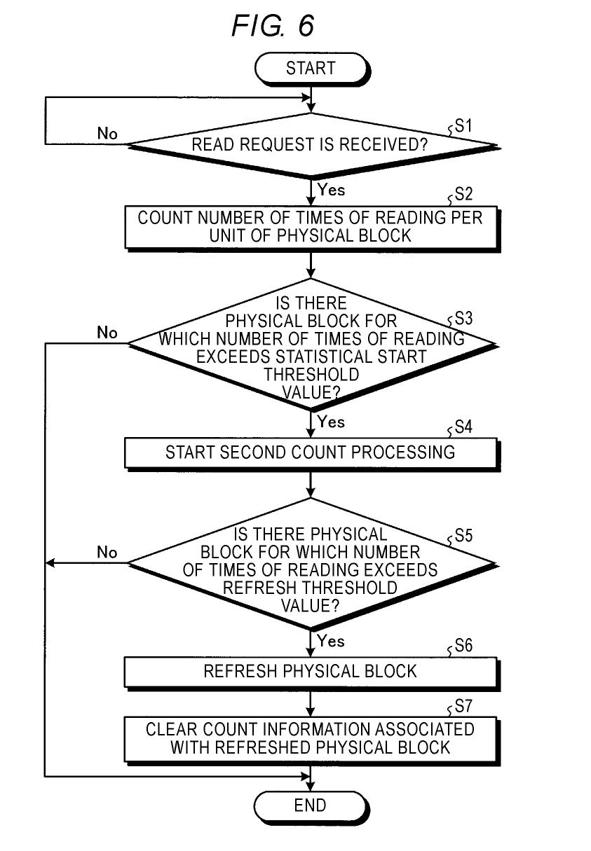

Thereafter, a count processing of the present embodiment will be described. FIG. 6 is a flow chart illustrating an example of a procedure of the first count processing according to the present embodiment.

The command controller 31 of the back end unit 30 determines whether the type of a command received from the front end unit 20 is a read request command (S1). The address translation unit 302 translates a logical address specified by a command transmitted from the front end unit 20 into a physical address in the NAND memory 11 using the address translation table 32.

When the read request command is not received (“No” in S1), the command controller 31 repeats the processing of S1.

When the command controller 31 receives the read request command (“Yes” in S1), the first counter 304 specifies a physical block 60 as the read request target based on the physical address obtained through translation by the address translation unit 302, and counts the number of times of reading per unit of the physical block 60 (S2). The first counter 304 updates the count information 53 stored in the RAM 37.

Then, the first counter 304 determines whether there is a physical block 60 for which the number of times of reading exceeds a statistical start threshold value (S3).

When there is no physical block 60 for which the number of times of reading exceeds the statistical start threshold value (“No” in S3), this processing ends.

When there is a physical block 60 for which the number of times of reading exceeds the statistical start threshold value (“Yes” in S3), the first counter 304 specifies a group G associated with the physical block 60. Then, the first counter 304 notifies the second counter 305 of the specified group G and allows the second counter 305 to start a second count processing (S4). The second count processing is a processing of counting the number of times of reading per unit of the notified group G, which is executed by the second counter 305. The specific flow of the second count processing will be described later.

Thereafter, the refresh controller 307 determines whether there is a physical block 60 for which the number of times of reading exceeds a refresh threshold value (S5).

When there is no physical block 60 for which the number of times of reading exceeds the refresh threshold value (“No” in S5), this processing ends.

When there is a physical block 60 for which the number of times of reading exceeds the refresh threshold value (“Yes” in S5), the refresh controller 307 refreshes the physical block 60 (S6). The refresh controller 307 notifies the first counter 304, the second counter 305, and the cache controller 306 of the refreshed physical block 60. The first counter 304 and the second counter 305 clear the count information 53 associated with the refreshed physical block 60, and returns the count information 53 to “0” (S7). Then, this processing ends.

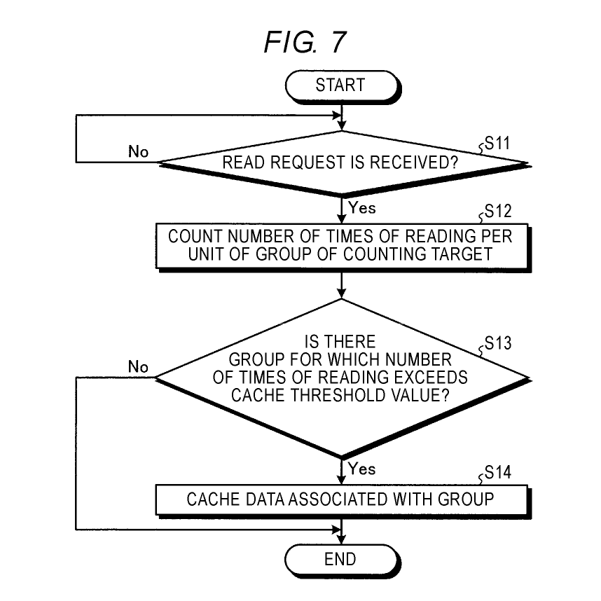

Next, a second count processing of the present embodiment will be described. FIG. 7 is a flow chart illustrating an example of a procedure of the second count processing according to the present embodiment. This processing is a processing starting from S4 in FIG. 6.

As in S1 of FIG. 6, the command controller 31 of the back end unit 30 determines whether the type of a command received from the front end unit 20 is a read request command (S11). When the read request command is not received (“No” in S11), the command controller 31 repeats the processing of S11.

When the command controller 31 receives the read request command (“Yes” in S11), the second counter 305 counts the number of times of reading per unit of the group G, of a counting target included in the physical block 60 for which the number of times of reading exceeds the statistical start threshold value (S12). The second counter 305 updates the number of times of reading of the group G, which is stored in the count information 53.

Then, the second counter 305 determines whether there is a group G for which the number of times of reading exceeds a cache threshold value (S13).

When there is no group G for which the number of times of reading exceeds the cache threshold value (“No” in S13), this processing ends.

When there is a group G for which the number of times of reading exceeds the cache threshold value (“Yes” in S13), the second counter 305 notifies the cache controller 306 of the group G.

The cache controller 306 caches data associated with the notified group G in the RAM 37 from the NAND memory 11, as the cache 52 (S14).

After the processing, since the data associated with the group G for which the number of times of reading exceeds the cache threshold value is cached in the cache 52, in the case where a read request of the data is received from the host 50, the data is read from the cache 52. Accordingly, the number of times of reading of the group G included in the physical block 60 is reduced, and thus, it is possible to reduce the number of times of reading of the physical block 60.

As described above, in the present embodiment, the number of times of reading is counted in two divided stages such that when the number of times of reading per unit of the physical block 60 exceeds the statistical start threshold value, the number of times of reading is counted per unit of the group G included in the physical block 60. Accordingly, desired data can be cached per unit of the group G which is a relatively small unit, instead of the unit of the physical block 60.

The flow charts described above with reference to FIGS. 6 and 7 are examples of procedures of the first count processing and the second count processing, and the execution timing of each processing is not limited thereto.

As described above, in the memory system 10 according to the present embodiment, the number of times of reading by the host 50 is counted per unit of the physical block 60. Then, when the number of times of reading per unit of the physical block 60 exceeds the statistical start threshold value, the number of times of reading is counted per predetermined unit of the group G or the like included in the physical block 60. Accordingly, in the memory system 10 of the present embodiment, caching of data of the NAND memory 11 can be implemented per predetermined unit of the group G or the like included in the physical block 60. That is, in the memory system 10 of the present embodiment, caching is performed per relatively small unit (e.g., per unit of the group G), instead of the unit of the physical block 60. Thus, the number of times of access to the NAND memory 11 can be reduced by caching a relatively small amount of data, and the cache area can be effectively utilized. That is, in the memory system 10 of the present embodiment, an increase of an amount of data to be cached can be prevented, and failure of the NAND memory 11 from wear can be delayed.

When counting is performed per unit of the group G for all read requests, the number of counting targets increases, thereby increasing the amount of data of the count information 53. Therefore, in the memory system 10 of the present embodiment, the number of times of reading per unit of the physical block 60 is counted in the first stage, and then, when the number of times of reading exceeds the statistical start threshold value, counting is performed on the number of times of reading per unit (e.g., per unit of the group G) for which a read request is made from the host 50, which is included in the physical block 60. Thus, the number of groups G as counting targets can be reduced.

In the memory controller 12 of the memory system 10 according to the present embodiment, both counting of the number of times of reading per unit of the physical block 60 and counting of the number of times of reading per unit of the group G are performed by the back end unit 30. Thus, it is possible to perform a processing of counting the number of times of reading without changing the configuration of the front end unit 20.

The memory system 10 according to the present embodiment executes refreshing on the physical block 60 for which the number of times of reading exceeds the refresh threshold value. In the memory system 10 according to the present embodiment, data of the group G included in the physical block 60 for which the number of times of reading is large is cached, thereby reducing the number of times of reading from the physical block 60. Thus, it is possible to further delay the timing at which the number of times of reading exceeds the refresh threshold value. In general, as the number of times of refreshing increases, the deterioration of the NAND memory 11 from wear worsens. However, in the memory system 10 according to the present embodiment, the deterioration of the NAND memory 11 from wear can be further delayed.

In the first embodiment described above, the second counter 305 sets the group G included in the physical block 60 for which the number of times of reading exceeds the statistical start threshold value, as a target for which the number of times of reading is counted. However, other conditions maybe further provided. For example, the second counter 305 may set groups G included in top five physical blocks 60 in descending order of the number of occurrences of read disturb, that is, in descending order of the number of errors per bit of read data, among the physical blocks 60 for which the number of times of reading exceeds the statistical start threshold value, as targets for which the number of times of reading is counted. This condition is employed in one example implementation, and the present disclosure is not limited thereto.

In the first embodiment described above, the memory controller 12 performs processing by the front end unit 20 and the back end unit 30 separately, but the present disclosure is not limited to this configuration. The configuration according to the first embodiment may also be applied to another memory controller that performs processing through a configuration where the front end unit 20 and the back end unit 30 are not separated.

### Second Embodiment

In the first embodiment described above, both the first count processing and the second count processing are executed by the back end unit. In the present embodiment, the front end unit executes the second count processing.

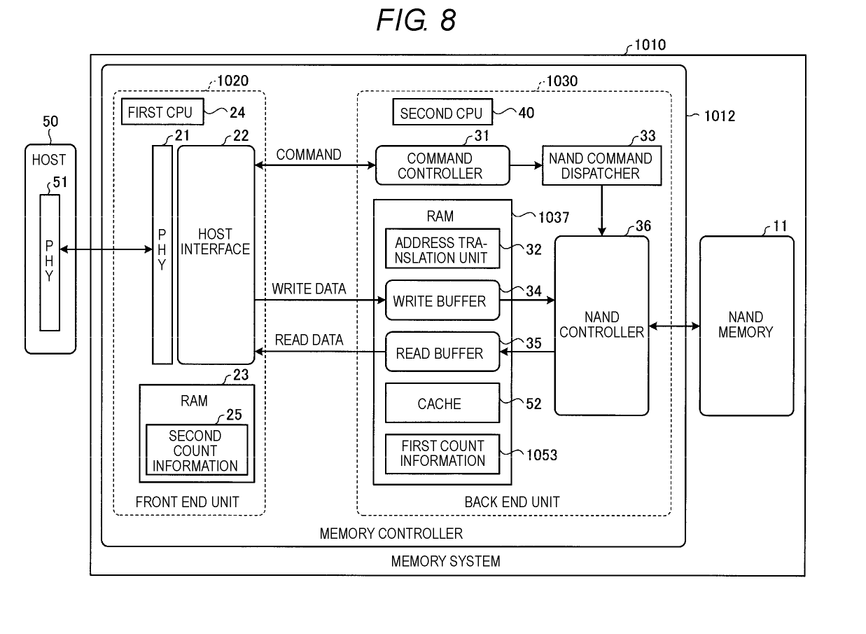

FIG. 8 is a view schematically illustrating an example of an entire configuration of a memory system 1010 according to the present embodiment. As illustrated in FIG. 8, as in the first embodiment, the memory system. 1010 includes a NAND memory 11 and a memory controller 1012. The configuration of the NAND memory 11 is the same as that in the first embodiment. In the present embodiment, explanation on details of the same configuration as that in the first embodiment will be omitted, and different features and configurations will be described in detail.

The memory controller 1012 of the present embodiment includes a front end unit 1020 and a back end unit 1030.

The front end unit 1020 of the present embodiment includes a PHY 21, a host interface 22, a first CPU 24, and a RAM 23.

As in the first embodiment, the first CPU 24 controls the front end unit 1020. The PHY 21 and the host interface 22 have the same functions as those in the first embodiment.

The RAM 23 stores second count information 25. The second count information 25 is a count result of data stored in the NAND memory 11, for each group G. The group G is an example of a second count unit in the present embodiment.

The back end unit 1030 of the present embodiment includes a command controller 31, a dispatcher 33, a NAND controller 36, a RAM 1037, and a second CPU 40.

The second CPU 40 controls the back end unit 1030 as in the first embodiment. The command controller 31, the dispatcher 33, and the NAND controller 36 have the same functions as those in the first embodiment.

The RAM 1037 of the present embodiment stores an address translation table 32, a write buffer 34, a read buffer 35, a cache 52, and first count information 1053.

The address translation table 32, the write buffer 34, the read buffer 35, and the cache 52 are the same as those in the first embodiment.

The first count information 1053 is a count result of data stored in the NAND memory 11, for each physical block 60. The physical block 60 is an example of a first count unit in the present embodiment.

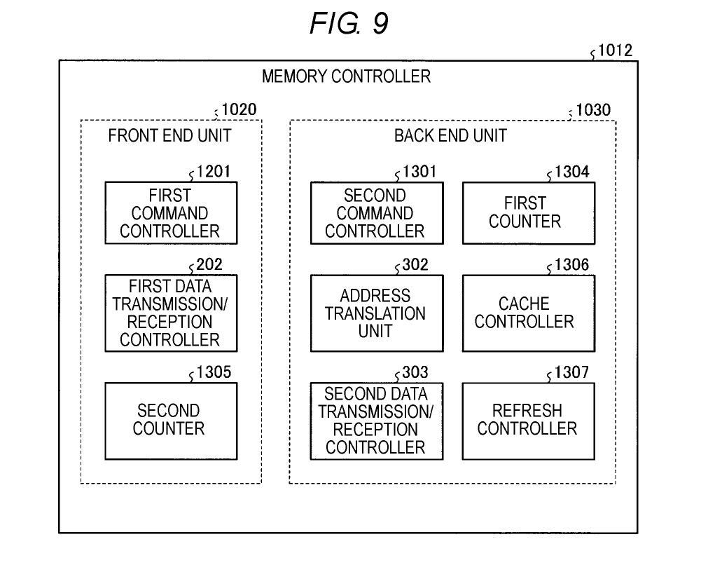

FIG. 9 is a view schematically illustrating an example of a function of the memory controller 1012 according to the present embodiment. As illustrated in FIG. 9, the front end unit 1020 of the memory controller 1012 of the present embodiment includes a first command controller 1201, a first data transmission/reception controller 202, and a second counter 1305.

The first data transmission/reception controller 202 has the same function as that in the first embodiment.

The second counter 1305 is notified about a logical address on a group G associated with a physical block 60 for which the number of times of reading by the host 50 exceeds a statistical start threshold value, by the back end unit 1030, and counts the number of times of reading for each group G. More specifically, when the target of a read request transmitted from the host 50 is a counting target, the second counter 1305 increases the number of times of reading of the group G, which is stored in the second count information 25.

When the number of times of reading of a certain group G exceeds a predetermined cache threshold value, the second counter 1305 of the present embodiment notifies the back end unit 1030 of a logical address on the group G. The notification to the back end unit 1030 is transmitted as, for example, a command.

When notified of the logical address on a group G included in a refreshed physical block 60 by the back end unit 1030, the second counter 1305 of the present embodiment returns the number of times of reading of the group G, which is stored in the second count information 25, to “0.” When a write request is made for a certain logical block 71 from the host 50, the second counter 1305 returns the number of times of reading of the group G including the certain logical block 71, which is stored in the second count information 25, to “0.”

The first command controller 1201 has the functions of the first embodiment, and controls transmission/reception of commands such as a command that notifies of the logical address on a group G as a counting target, which is to be transmitted from the back end unit 1030, a command that notifies of the logical address on a group G included in a refreshed physical block 60, and a command that notifies of the logical address on a group G as a cache target, which is to be transmitted to the back end unit 1030.

As illustrated in FIG. 9, the back end unit 1030 of the present embodiment includes a second command controller 1301, an address translation unit 302, a second data transmission/reception controller 303, a first counter 1304, a cache controller 1306, and a refresh controller 1307.

The address translation unit 302 and the second data transmission/reception controller 303 have the same functions as those in the first embodiment.

The first counter 1304 has the functions of the first embodiment. When the number of times of reading of a certain physical block 60 by the host 50 exceeds a statistical start threshold value, the first counter 1304 notifies the front end unit 1020 about the logical address of a group G included in the physical block 60 for which the number of times of reading exceeds the statistical start threshold value. The notification to the front end unit 1020 is transmitted as, for example, a command by the command controller 31.

The cache controller 1306 has the functions of the first embodiment, and caches data stored in a data area indicated by the logical address on a group G as a cache target notified by the front end unit 1020, in the cache 52.

The refresh controller 1307 has the functions of the first embodiment, and notifies the front end unit 1020 of the logical address on a group G included in a refreshed physical block 60.

The second command controller 1301 has the functions of the first embodiment, and controls transmission/reception of commands such as a command that notifies of the logical address on a group G included in a physical block 60 for which the number of times of reading exceeds a statistical start threshold value, which is to be transmitted to the front end unit 1020, a command that notifies of the logical address on a group G as a cache target, which is to be transmitted from the front end unit 1020, and a command that notifies of the logical address on a group G included in a refreshed physical block 60, which is to be transmitted to the front end unit 1020.

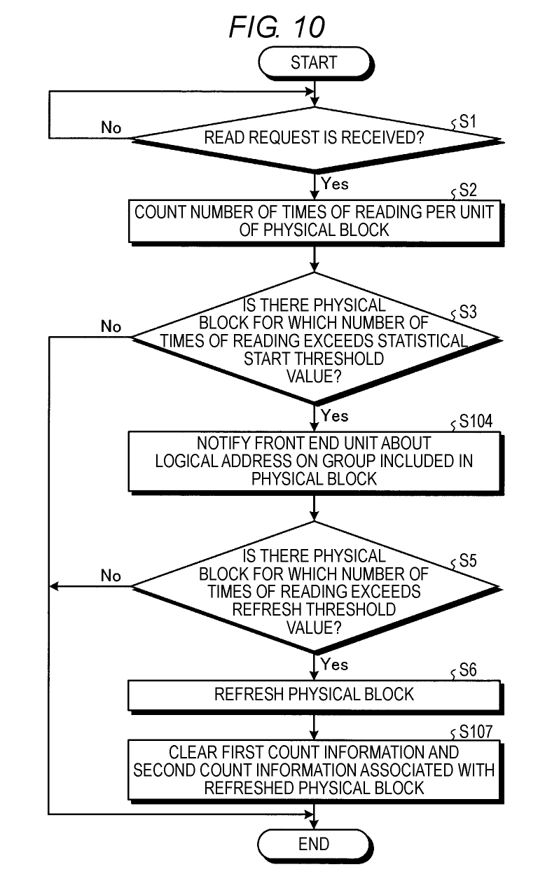

Thereafter, a count processing of the present embodiment will be described. FIG. 10 is a flow chart illustrating an example of a procedure of the first count processing according to the present embodiment. The processing from receiving a read request in S1 to determining whether there is a physical block 60 for which the number of times of reading exceeds a statistical start threshold value in S3 are the same as those in the first embodiment.

When there is a physical block 60 for which the number of times of reading exceeds the statistical start threshold value (“Yes” in S3), the first counter 1304 specifies a logical address on a group G associated with the physical block 60 using the address translation table 32. Then, the first counter 1304 notifies the front end unit 1020 about the logical address on the group G associated with the physical block 60 for which the number of times of reading exceeds the statistical start threshold value (S104).

The processing of determining whether there is a physical block 60 for which the number of times of reading exceeds a refresh threshold value in S5 to the processing of refreshing the physical block 60 for which the number of times of reading exceeds the refresh threshold value in S6 are the same as those in the first embodiment.

After the processing in S6, the refresh controller 1307 notifies the first counter 1304 and the cache controller 1306 of the refreshed physical block 60. The refresh controller 1307 notifies the front end unit 1020 about the logical address on a group G included in the refreshed physical block 60.

Then, the first counter 1304 clears the first count information 1053 associated with the refreshed physical block 60, and returns the first count information 1053 to “0.” The second counter 1305 clears the second count information 25 associated with the group G included in the refreshed physical block 60, which is notified by the back end unit 1030, and returns the second count information 25 to “0” (S107). Then, this processing ends.

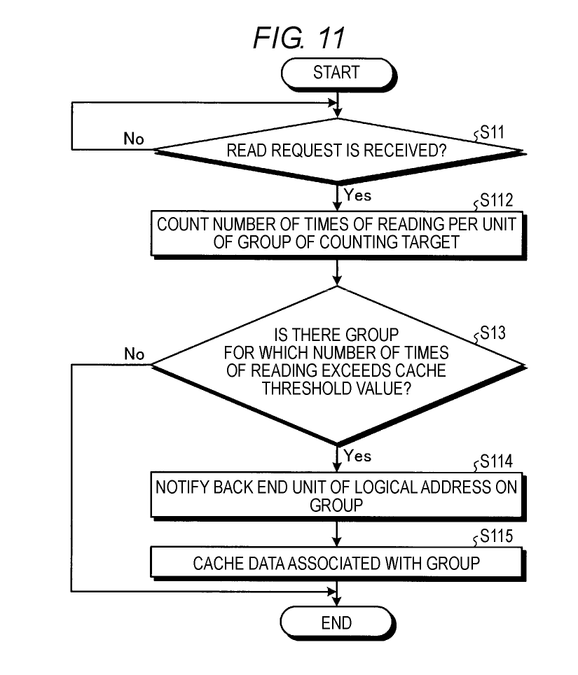

Next, a second count processing of the present embodiment will be described. FIG. 11 is a flow chart illustrating an example of a procedure of the second count processing according to the present embodiment.

The read request reception processing in S11 is the same as that in the first embodiment. In S112, the second counter 1305 counts the number of times of reading per unit of the group G, of a counting target included in the physical block 60 for which the number of times of reading exceeds the statistical start threshold value, which is notified by the back end unit 1030 (S112). The second counter 1305 updates the number of times of reading of the group G, which is stored in the second count information 25.

The processing of determining whether there is a group G for which the number of times of reading exceeds a cache threshold value in S13 is the same as that in the first embodiment.

When there is a group G for which the number of times of reading exceeds the cache threshold value (“Yes” in S13), the second counter 1305 notifies the back end unit 1030 of the logical address on the group G (S114).

Then, the cache controller 1306 caches data stored in a data area indicated by the logical address on the group G as a cache target, which is notified by the front end unit 1020, in the cache 52 (S115).

In this manner, in the memory system 1010 of the present embodiment, the number of times of reading per unit of the physical block 60 is counted by the back end unit 1030, and the number of times of reading per unit of the group G is counted by the front end unit 1020. Therefore, in the memory system 1010 of the present embodiment, in addition to the effects of the first embodiment, it is possible to disperse a processing load imposed on a processing of counting the number of times of reading by the front end unit 1020 and the back end unit 1030.

In this manner, according to the memory system 10 (1010) of each of the above-described embodiments, the failure of the NAND memory 11 due to wear can be delayed. Therefore, according to the memory system 10 (1010) of each of the above-described embodiments, for example, it is possible to prevent the occurrence of read disturb in the physical block 60. According to the memory system 10 (1010) of each of the above described embodiments, the failure of the NAND memory 11 due to wear can be delayed, thereby preventing the degradation of a bit error rate (BER) of data stored in the physical block 60.

According to the memory system 10 (1010) of each of the above described embodiments, since the time until the physical block 60 is refreshed can be delayed, the advancing of the program/erase cycle (P/E cycle) counter can be delayed. In general, the lifetime of the NAND memory 11 is determined by the P/E cycle. Thus, according to the memory system 10 (1010) of each of the above-described embodiments, it is possible to delay the advancing of the P/E cycle counter, and thus, to use the NAND memory 11 for a longer period of time.

### Modification 1

In each of the above-described embodiments, the second counter 305 (1305) counts the number of times of reading for each group G of a logical block, but the second count unit is not limited thereto. The second count unit only has to have a size smaller than the first count unit (the physical block 60) and including at least one logical block 71 that is a unit for which a read request is made from the host 50.

For example, the second counter 305 (1305) may count the number of times of reading by the host 50 for each cluster 70, instead of the group G of the logical block. In this case, the cluster 70 is an example of the second count unit in the present modification. In general, the cluster 70 is smaller than the group G. Thus, when this configuration is employed, the memory system 10 (1010) can further reduce the amount of data as a cache target.

### Modification 2

The second counter 305 (1305) may count the number of times of reading by the host 50 for each logical block 71. In this case, the logical block 71 is an example of the second count unit in the present modification. The logical block 71 is smaller than the group G or the cluster 70. Thus, when this configuration is employed, the memory system 10 (1010) can further reduce the amount of data as a cache target.

### Modification 3

The second counter 305 (1305) may count the number of times of reading by the host 50 for each physical page P. In this case, the physical page P is an example of the second count unit in the present modification. The physical page P is larger than the group G, and thus, the number of counting targets is reduced. Thus, when this configuration is employed, the memory system 10 (1010) can reduce the amount of data in the count information 53 (or the second count information 25).

### Modification 4

In each of the above-described embodiments, the memory controller 12 (1012) counts the number of times of reading in the two stages of the first count processing and the second count processing. However, the present disclosure is not limited to the two stages, and the number of times of reading may be counted by gradually reducing the count unit. For example, the memory controller 12 (1012) may count the number of times of reading for each physical block 60, in a first stage, count the number of times of reading for each physical page P included in the physical block 60 for which the number of times of reading exceeds a statistical start threshold value, in a second stage, and count the number of times of reading for each logical block 71 included in the physical page P for which the number of times of reading exceeds a statistical start threshold value, in a third stage.

In the case where this configuration is employed, when the number of times of reading exceeds a cache threshold value for a unit (e.g., the logical block 71) indicating the smallest data area among units (e.g., the physical block 60, the physical page P, and the logical block 71) by which the number of times of reading is counted, the memory controller 12 (1012) caches data stored in a data area of the NAND memory 11, which is indicated by the unit. As in the present modification, the memory system 10 (1010) may employ various configurations for the unit by which the number of times of reading is counted.

### Modification 5

In each of the above-described embodiments, the cache 52 is set as an area within the RAM 37 (1037) of the back end unit 30 (1030) of the memory controller 12 (1012), but the place where the cached data is stored is not limited thereto. For example, the cache 52 may be provided in a DRAM or the like outside the memory controller 12 (1012), or may be set as an area within the RAM 23 of the front end unit 1020.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a non-volatile memory device; and
a memory controller configured to control the memory device, wherein the memory controller includes:
a first counting circuit configured to count a number of times reading is performed on a first unit of data stored in the memory device, wherein the memory controller is configured to erase data of the first unit of data collectively from the memory device;
a second counting circuit configured to count a number of times reading is performed on a second unit of data stored in the memory device, which has a size smaller than that of the first unit of data and is a part of the first unit of data, when the number of times reading has been performed on the first unit of data exceeds a first threshold value; and
a cache control circuit configured to cache the second unit of data in response to a read request for the second unit of data, when the number of times reading has been performed on the second unit of data exceeds a second threshold value which is smaller than the first threshold value.

2. The memory system according to claim 1, wherein the memory controller includes:
a first circuit configured to receive a command from a host, and return a response to the command, to the host; and
a second circuit configured to receive a request corresponding to the command from the first circuit, and access the memory device based on the request,
wherein the second circuit includes the first counting circuit and the second counting circuit.

3. The memory system according to claim 1, wherein the memory controller includes:
a first circuit configured to receive a command from a host, and return a response to the command, to the host; and
a second circuit configured to receive a request corresponding to the command from the first circuit, and access the memory device based on the request,
wherein the second circuit includes the first counting circuit, and the first circuit includes the second counting circuit.

4. The memory system according to claim 3,
wherein the first counting circuit sends a first notification to the first circuit when the number of times reading has been performed on the first unit of data has exceeded the first threshold value, and
the second counting circuit counts the number of times reading has been performed on the second unit of data after receiving the first notification, and sends a second notification to the cache control circuit to cache the second unit of data when the number of times reading has been performed on the second unit of data has exceeded the second threshold value.

5. The memory system according to claim 4, wherein the second circuit sends a third notification to the first circuit when the first unit of data is refreshed.

6. The memory system according to claim 1, wherein the second unit of data has a size of a logical block which is a minimum unit of an access by the host.

7. The memory system according to claim 1, wherein the second unit of data has a size of a group of logical blocks, wherein a logical block is a minimum unit of access by the host.

8. The memory system according to claim 7, wherein the group of logical blocks make up a page, which is a unit of data reading from and writing to the memory device by the memory controller.

9. The memory system according to claim 1, wherein the memory controller further includes a refresh control circuit configured to perform a refresh operation on the first unit of data when the number of times reading has been performed on the first unit of data exceeds a third threshold value which is larger than the first threshold value.

10. The memory system according to claim 9, wherein the refresh control circuit is configured to notify the first counting circuit to reset the number of times reading has been performed on the first unit of data to zero and the second counting circuit to reset the number of times reading has been performed on the second unit of data to zero.

11. A method of controlling a memory system including a non-volatile memory device, said method comprising:
counting a number of times reading is performed on a first unit of data;
counting a number of times reading is performed on a second unit of data, which has a size smaller than that of the first unit of data and is a part of the first unit of data, when the number of times reading has been performed on the first unit of data exceeds a first threshold value; and
caching the second unit of data in response to a read request for the second unit of data, when the number of times reading has been performed on the second unit of data exceeds a second threshold value which is smaller than the first threshold value.

12. The method according to claim 11, wherein the second unit of data has a size of a logical block which is a minimum unit of an access by the host.

13. The method according to claim 11, wherein the second unit of data has a size of a group of logical blocks, wherein a logical block is a minimum unit of access by the host.

14. The method according to claim 13, wherein the group of logical blocks make up a page, which is a unit of data reading from and writing to the memory device by the memory controller.

15. The method according to claim 11, further comprising:
performing a refresh operation on the first unit of data when the number of times reading has been performed on the first unit of data exceeds a third threshold value which is larger than the first threshold value.

16. The method according to claim 15, further comprising:
upon performing the refresh operation on the first unit of data, resetting the number of times reading has been performed on the first unit of data to zero and also resetting the number of times reading has been performed on the second unit of data to zero.

17. A memory system comprising:
a non-volatile memory device; and
a memory controller configured to control the memory device, wherein the memory controller is configured to:
track a number of times reading has been performed for data stored in a first count unit of the memory device,
when reading has been performed on the first count unit greater than a first threshold number of times, track a number of times reading is performed on each of different second count units of the memory device that are within the first count unit, and
cache data read from the memory device if the data is read from the memory device at a location corresponding to one of the second count units for which reading has been performed more than a second threshold number of times.

18. The memory system according to claim 17, wherein the memory controller includes:
a first circuit configured to receive a command from a host, and return a response to the command, to the host; and
a second circuit configured to receive the command from the first circuit, and access the memory device based on the command,
wherein the second circuit is configured to track the number of times reading has been performed on the first count unit, and track the number of times reading is performed on each of the different second count units.

19. The memory system according to claim 17, wherein the memory controller includes:
a first circuit configured to receive a command from a host, and return a response to the command, to the host; and
a second circuit configured to receive the command from the first circuit, and access the memory device based on the command,
wherein the second circuit is configured to track the number of times reading has been performed on the first count unit, and the first circuit is configured to track the number of times reading is performed on each of the different second count units.

20. The memory system according to claim 19,
wherein the second circuit sends a first notification to the first circuit when the number of times reading has been performed on the first count unit has exceeded the first threshold value, and
the first circuit counts the number of times reading has been performed on each of the different second count units after receiving the first notification.
